(19) United States
(12) Patent Application Publication
(10) Pub. No.: US 2019/0127576 A1
(43) Pub. Date: May 2, 2019

(54) PHOSPHONATE BASED HALOGEN-FREE COMPOSITIONS FOR PRINTED CIRCUIT BOARD APPLICATIONS

(71) Applicant: FRX POLYMERS, INC., Chelmsford, MA (US)

(72) Inventors: Lawino KAGUMBA, Cambridge, MA (US); Jan-Pleun LENS, Boston, MA (US)

(21) Appl. No.: 16/173,296

(22) Filed: Oct. 29, 2018

Related U.S. Application Data
(60) Provisional application No. 62/578,142, filed on Oct. 27, 2017.

(51) Int. Cl. C08L 71/02; C08K 5/29; C08L 85/02; C08L 63/00; C08J 5/24

(52) U.S. Cl. CPC C08L 71/02; C08K 5/29; H05K 1/0353; C08L 63/00; C08J 5/24; C08L 85/02

(57) ABSTRACT

Disclosed is a resin composition containing phosphonate and polyphenylene oxide (PPO) oligomers/polymers useful for coating prepregs used to make copper clad laminates used in printed circuit boards. The compositions contain crosslinking agents used to ensure a dense crosslink network as demonstrated by high glass transition temperatures (Tg's).

### CROSS-REFERENCE TO RELATED APPLICATIONS

This application claims priority to U.S. Provisional Application No. 62/578,142 filed Oct. 27, 2017, entitled “PHOSPHONATE BASED HALOGEN-FREE COMPOSITIONS FOR PRINTED CIRCUIT BOARD APPLICATIONS.”

### GOVERNMENT INTERESTS

Not applicable

### PARTIES TO A JOINT RESEARCH AGREEMENT

Not applicable

### INCORPORATION BY REFERENCE OF MATERIAL SUBMITTED ON A COMPACT DISC

Not applicable

### BACKGROUND

Not applicable

### SUMMARY OF THE INVENTION

This present invention relates to a resin composition containing phosphonate and polyphenylene oxide (PPO) oligomers/polymers useful for coating prepregs used to make copper clad laminates used in printed circuit boards. The invention describes compositions containing crosslinking agents used to ensure a dense crosslink network as demonstrated by high glass transition temperatures (Tg's) greater than 220° C. Improving the crosslink density of cured laminates is known to improve the thermal and hydrolytic resistance of laminates.

Some embodiments provide a curable composition comprising phosphonate oligomer, polymer or copolymer; a polyphenylene ether resin; and a crosslinking compound.

In some embodiments, the crosslinking compound comprises vinyl functionality, epoxy functionality, or both vinyl and epoxy functionality, or both vinyl and hydroxy functionality.

In some embodiments, the crosslinking compound comprises of triallyl isocyanurate, triglycidyl isocyanurate, glycidyl methacrylate, 4-(glycidyloxy)-styrene, vinyl benzyl alcohol, 2-(4-ethenylphenoxymethyl)oxirane, vinyl terminated phosphonate oligomer

In some embodiments, the phosphonate copolymer contains phosphonate groups and carbonate groups or ester groups

Some embodiments employ 30 wt % or less phosphonate component and wherein the composition meets V0 at 0.65 mm or less.

Some embodiments employ 30 wt % or less phosphonate component and wherein the composition has a Df at 1 GHz<0.007.

Some embodiments have a Tg of at least 200° C. when measured with DMA.

Some embodiments provide a curable composition comprising phosphonate oligomer, polymer or copolymer; polyphenylene ether resin; one or more co-resin; and a crosslinking compound.

In some embodiments, the co-resin is an epoxy resin, a cyanate ester, or benzoxazine resin

Some embodiments employ 30 wt % or less phosphonate component and wherein the composition meets V0 at 0.65 mm or less.

Some embodiments employ 30 wt % or less phosphonate component and wherein the composition has a Df at 1 GHz<0.007.

Some embodiments have a Tg of at least 200° C.

Some embodiments provide a prepreg formulation comprising a thermosetting resin formulation comprising a phosphonate oligomer, polymer or copolymer; a polyphenylene ether resin; and a crosslinking compound, wherein the thermosetting resin formulation is impregnated onto a reinforcing material.

Some embodiments provide a laminate comprising a prepreg comprising a thermosetting resin formulation comprising a phosphonate oligomer, polymer or copolymer; a polyphenylene ether resin; and a crosslinking compound, wherein the thermosetting resin formulation is impregnated onto a reinforcing material.

### DETAILED DESCRIPTION

Formulations containing polyphenylene ether or polyphenylene oxide (PPO) oligomers are currently used to make laminates due to their excellent dielectric properties, particularly low dissipation factor. These PPO oligomers can contain hydroxyl or vinyl end groups and crosslinking agents containing trifunctional vinyl groups such as triallyl isocyanurates (TAIC) have been used to crosslink with PPO oligomers. TAIC possesses thermally stable triazine ring providing improved heat and hydrolytic resistance.

Phosphonate oligomers are known to crosslink via the reaction of phosphonate groups with secondary alcohols generated from the ring opening reaction of epoxy resins. Therefore, in order to achieve a crosslinked network between the phosphonate oligomers and the PPO oligomers containing vinyl end groups, crosslinking compounds that contain both vinyl and epoxy end groups were used in the formulation to ensure reaction between both compounds. The resulting laminates have high glass transition temperatures and low dissipation factor Df<0.007 or even as low as 0.003-0.005.

The above summary of the present invention is not intended to describe each illustrated embodiment or every possible implementation of the present invention. The detailed description, which follows, particularly exemplifies these embodiments.

Before the present compositions and methods are described, it is to be understood that they are not limited to the particular compositions, methodologies or protocols described, as these may vary. It is also to be understood that the terminology used in the description is for the purpose of describing the particular versions or embodiments only, and is not intended to limit their scope which will be limited only by the appended claims.

It must also be noted that as used herein and in the appended claims, the singular forms “a”, “an”, and “the” include plural reference unless the context clearly dictates otherwise. Unless defined otherwise, all technical and scientific terms used herein have the same meanings as commonly understood by one of ordinary skill in the art. Although any methods and materials similar or equivalent to those described herein can be used in the practice or testing of embodiments disclosed, the preferred methods, devices, and materials are now described.

“Optional” or “optionally” means that the subsequently described event or circumstance may or may not occur, and that the description includes instances where the event occurs and instances where it does not.

“Substantially no” means that the subsequently described event may occur at most about less than 10% of the time or the subsequently described component may be at most about less than 10% of the total composition, in some embodiments, and in others, at most about less than 5%, and in still others at most about less than 1%.

The term “carbonate” as used herein is given its customary meaning, e.g., a salt of carbonic acid containing the divalent, negative radical CO or an uncharged ester of this acid. A “diaryl carbonate” is a carbonate with at least two aryl groups associated with the CO radical, the most predominant example of a diaryl carbonate is diphenyl carbonate; however, the definition of diaryl carbonate is not limited to this specific example.

The term “aromatic dihydroxide” is meant to encompass any aromatic compound with at least two associated hydroxyl substitutions. Examples of “aromatic hydroxides” include but are not limited to benzene diols such as hydroquinone and any bisphenol or bisphenol containing compounds.

The terms “flame retardant,” “flame resistant,” “fire resistant,” or “fire resistance,” as used herein, means that the composition exhibits a limiting oxygen index (LOI) of at least 27. “Flame retardant,” “flame resistant,” “fire resistant,” or “fire resistance,” may also be tested by measuring the after-burning time in accordance with the UL test (Subject 94). In this test, the tested materials are given classifications of UL-94 V-0, UL-94 V-1 and UL-94 V-2 on the basis of the results obtained with the ten test specimens. Briefly, the criteria for each of these UL-94-V-classifications are as follows:

UL-94 V-0: the total flaming combustion for each specimen after removal of the ignition flame should not exceed 10 seconds and the total flaming combustion for 5 specimens should not exceed 50 seconds. None of the test specimens should release and drips which ignite absorbent cotton wool.

UL-94 V-1: the total flaming combustion for each specimen after removal of the ignition flame should not exceed 30 seconds and the total flaming combustion for 5 specimens should not exceed 250 seconds. None of the test specimens should release any drips which ignite absorbent cotton wool.

UL-94 V-2: the total flaming combustion for each specimen after removal of the ignition flame should not exceed 30 seconds and the total flaming combustion for 5 specimens should not exceed 250 seconds. Test specimens may release flaming particles, which ignite absorbent cotton wool.

Fire resistance may also be tested by measuring after-burning time. These test methods provide a laboratory test procedure for measuring and comparing the surface flammability of materials when exposed to a prescribed level of radiant heat energy to measure the surface flammability of materials when exposed to fire. The test is conducted using small specimens that are representative, to the extent possible, of the material or assembly being evaluated. The rate at which flames travel along surfaces depends upon the physical and thermal properties of the material, product or assembly under test, the specimen mounting method and orientation, the type and level of fire or heat exposure, the availability of air, and properties of the surrounding enclosure. If different test conditions are substituted or the end-use conditions are changed, it may not always be possible by or from this test to predict changes in the fire-test-response characteristics measured. Therefore, the results are valid only for the fire test exposure conditions described in this procedure.

Embodiments of the invention are directed to polymer compositions including a polyphenylene ether component, a phosphonate component, a crosslinking agent and optionally a polymer resin component such as epoxy and prepregs and copper clad laminates (CCL) including these compositions. Further embodiments are directed to methods for making these compositions, CCLs, and prepregs, and articles of manufacture containing these compositions, CCLs, and prepregs.

The compositions of embodiments contain polyphenylene ethers such as polyphenylene oxide (PPO) or polyphenylene ether oligomers or polymers. The PPO oligomers are functionalized with either hydroxyl groups or vinyl groups. Examples of PPO oligomers include Noryl SA90 and Noryl SA9000 manufactured by SABIC. Other examples include vinyl benzene polyphenylene ether resins.

The composition of embodiments contains one or more crosslinking agents which consist of compounds that contain vinyl functionality, hydroxyl and epoxy functionality on separate molecules or both vinyl and epoxy functionality on the same molecule, or both vinyl and hydroxy functionality on the same molecule. Example triallyl isocyanurate, triglycidyl isocyanurate, glycidyl methacrylate, 4-(glycidyloxy)-styrene, vinyl benzyl alcohol, 2-(4-ethenylphenoxymethyl)oxirane.

In some embodiments the crosslinking agent is a vinyl functionalized phosphonate oligomer. This includes phosphonate oligomers or polymers with vinyl end-groups or branched groups containing vinyl end groups. The vinyl functionalized oligomers can be prepared by reacting the hydroxyl groups of the phosphonate oligomer with vinyl containing compounds or via phosphonate reaction with hydroxy-vinyl compounds.

The compositions of embodiments may contain any polymer resin known in the art. In particular embodiments, the polymer resin may be an epoxy resin, and in certain embodiments, the resin may contain glycidyl groups, alicyclic epoxy groups, oxirane groups, ethoxyline groups, or similar epoxy groups or combinations thereof that can react with epoxy groups associated with the epoxy containing phosphonate polymers, copolymers, oligomers and co-oligomers of this invention. Such epoxy resins are well known in the art and include, but are not limited to, novolac-type epoxy resin, cresol-novolac epoxy resin, triphenolalkane-type epoxy resin, aralkyl-type epoxy resin, aralkyl-type epoxy resin having a biphenyl skeleton, biphenyl-type epoxy resin, dicyclopentadiene-type epoxy resin, heterocyclic-type epoxy resin, epoxy resin containing a naphthalene ring, a bisphenol-A type epoxy compound, a bisphenol-F type epoxy compound, stilbene-type epoxy resin, trimethylol-propane type epoxy resin, terpene-modified epoxy resin, linear aliphatic epoxy resin obtained by oxidizing olefin bonds with peracetic acid or a similar peracid, alicyclic epoxy resin, or sulfur-containing epoxy resin. In some embodiments, the epoxy resin may be composed of two or more epoxy resins of any of the aforementioned types. In particular embodiments, the epoxy resins may be aralkyl-type epoxy resins, such as epoxy resins derived from bisphenol A or 4,4′-methylene dianiline. The epoxy may also contain one or more additional components such as, for example, a benzoxazine compound or resin, and in some embodiments, the novel epoxy containing phosphonate monomers, polymers, copolymers, oligomers and co-oligomers may be used as epoxy modifiers, chain extenders or crosslinkers for epoxy resins, or epoxy hardeners in such epoxy resin polymer compositions.

In some embodiments, the polymer resin may be a cyanate ester resin. Such resins are known in the art and can include any resin having units of —OCN. In certain embodiments, the cyanate esters may contain units of Ar—O—CN, where Ar is substituted or unsubstituted benzene, biphenyl, naphthalene, phenol novolac, bisphenol A, bisphenol A novolac, bisphenol F, bisphenol F novolac, or phenolphthalein, and in some embodiments Ar may be bonded with substituted or unsubstituted dicyclopentadienyl. Examples of cyanate ester resins include, but are not limited to:

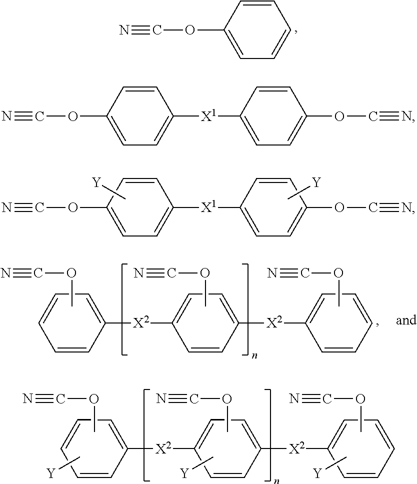

where each X¹ and X² are independently —C(CH₃)₂—, —CH(CH₃)—, —CH₂—, SO₂, O, substituted or unsubstituted benzene, biphenyl, naphthalene, phenol novolac, bisphenol A, ester, ring-substituted fluorenones, hydrogenated bisphenol A, bisphenol A novolac, bisphenol F, or bisphenol F novolac function groups; n is an integer equal to 1 to 100; and Y is C₁₋₂₀ alkyl, C₂₋₂₀ alkene, C₁₋₂₀ alkyne, C₅₋₂₀ cycloalkyl, or C₆₋₂₀ aryl.

In some embodiments, the polymer resin may be a benzoxazine resin. Such resins are known in the art and can include bisphenol A benzoxazine, bisphenol F benzoxazine, phenolphthalein benzoxazine, and the like and combinations thereof. Examples of benzoxazine resins include, but are not limited to:

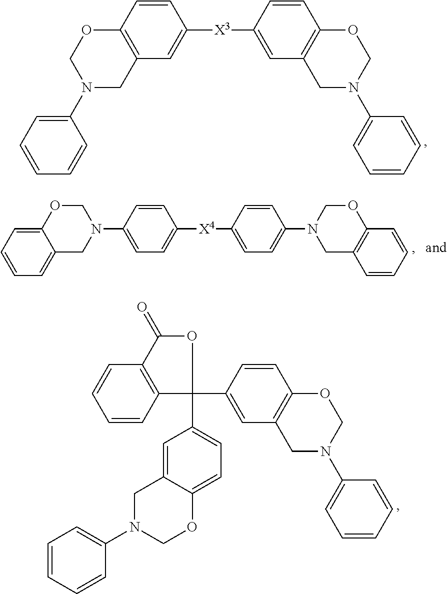

wherein each X³ and X⁴ are independently —C(CH₃)₂—, —CH(CH₃)—, —CH₂—, SO₂, O, substituted or unsubstituted benzene, biphenyl, naphthalene, phenol novolac, bisphenol A, ester, ring-substituted fluorenones, hydrogenated bisphenol A, bisphenol A novolac, bisphenol F, or bisphenol F novolac.

Description General Phosphonate Structures

Embodiments of the invention are not limited by the type of phosphonate component included and may include, for example, polyphosphonates, branched polyphosphonates, or random or block copolyphosphonates, co-oligo(phosphonate ester)s, or co-oligo(phosphonate carbonate)s, phosphonate oligomers, branched phosphonate oligomers, and in certain embodiments, the phosphonate component may have the structures described and claimed in U.S. Pat. Nos. 7,645,850, 7,816,486, 8,389,664, 8,563,638, 8,648,163, 8,779,041, 8,530,044, each of which is hereby incorporated by reference in its entirety.

Such phosphonate components may include repeating units derived from diaryl alkylphosphonates or diaryl arylphosphonates. For example, in some embodiments, such phosphonate components include structural units illustrated by Formula I:

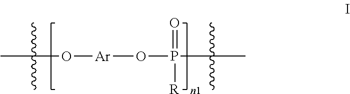

where Ar is an aromatic group and —O—Ar—O— may be derived from an aromatic dihydroxy compound or aromatic diol, R is a C1-20 alkyl, C2-20 alkene, C2-20 alkyne, C5-20 cycloalkyl, or C6-20 aryl, and n1 is an integer from 2 to about 200, 2 to about 100, 2 to about 75, 2 to about 50, 2 to about 20, 2 to about 10, or 2 to about 5, or any integer between these ranges.

The term “aromatic diol” is meant to encompass any aromatic or predominately aromatic compound with at least two associated hydroxyl substitutions of the formula (II)

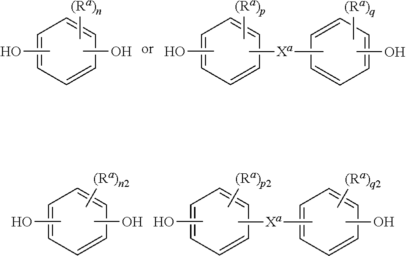

### (II)

wherein n2, p2, and q2 are each independently 0, 1, 2, 3, or 4; Ra is independently at each occurrence unsubstituted or substituted C1-10 hydrocarbyl; and Xa is a single bond, —O—, —S—, —S(O)—, —S(O)2-, —C(O)—, or a C1-18 hydrocarbylene, which can be cyclic or acyclic, aromatic or non-aromatic, and can further comprise one or more heteroatoms selected from oxygen, nitrogen, sulfur, silicon, or phosphorus. As used herein, the term “hydrocarbyl”, whether used by itself, or as a prefix, suffix, or fragment of another term, refers to a residue that contains only carbon and hydrogen unless it is specifically identified as “substituted hydrocarbyl”. The hydrocarbyl residue can be aliphatic or aromatic, straight-chain, cyclic, bicyclic, branched, saturated, or unsaturated. It can also contain combinations of aliphatic, aromatic, straight chain, cyclic, bicyclic, branched, saturated, and unsaturated hydrocarbon moieties. The term “substituted” means including at least one substituent such as a hydroxyl, amino, thiol, carboxyl, carboxylate, amide, nitrile, sulfide, disulfide, nitro, C1-18 alkyl, C1-18 alkoxyl, C6-18 aryl, C6-18 aryloxyl, C7-18 alkylaryl, or C7-18 alkylaryloxyl. The term “substituted” further permits inclusion of halogens (i.e., F, Cl, Br, I).

Some illustrative examples of specific dihydroxy compounds include the following: bisphenol compounds such as 4,4′-dihydroxybiphenyl, 1,4-dihydroxynaphthalene, 1,5-dihydroxynaphthalene, 1,6-dihydroxynaphthalene, 2,6-dihydroxynaphthalene, 2,7-dihydroxynaphthalene, bis(4-hydroxyphenyl)methane, bis(4-hydroxyphenyl)phenylmethane, bis(4-hydroxyphenyl)diphenylmethane, bis(4-hydroxy-3,5-dimethylphenyl)methane, bis(4-hydroxy-3,5-dichlorophenyl)methane, bis(4-hydroxy-3,5-dibromophenyl)methane, bis(4-hydroxy-3-methylphenyl)methane, bis(4-hydroxy-3-chlorophenyl)methane, bis(4-hydroxyphenyl)-1-naphthylmethane, 1,2-bis(4-hydroxyphenyl)ethane, 1,1-bis(4-hydroxyphenyl)-1-phenylethane, 2,2-bis(4-hydroxyphenyl)propane (“bisphenol A” or “BPA”), 2-(4-hydroxyphenyl)-2-(3-hydroxyphenyl)propane, 1,1-bis(4-hydroxyphenyl)cyclopentane, 1,1-bis(4-hydroxyphenyl)cyclohexane, 1,1-bis(4-hydroxy-3-methylphenyl)cyclohexane, 1,1-bis-(4-hydroxyphenyl)-3,3,5-trimethylcyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantane, alpha, alpha′-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxy-3,5-dimethylphenyl)propane, 2,2-bis(4-hydroxy-3-chlorophenyl)propane, 2,2-bis(4-hydroxy-3,5-dichlorophenyl)propane, 4,4′-dihydroxybenzophenone, bis(4-hydroxy-3,5-dimethylphenyl)ketone, bis(4-hydroxy-3,5-dichlorophenyl)ketone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl) sulfide, bis(4-hydroxyphenyl)sulfoxide, bis(4-hydroxyphenyl)sulfone, 9,9-bis(4-hydroxyphenyl)fluorene, 2,7-dihydroxypyrene, 6,6′-dihydroxy-3,3,3′,3′-tetramethylspiro(bis)indane (“spirobiindane bisphenol”), phenolphthalein and phenolphthalein derivatives, 3,3-bis(4-hydroxyphenyl)phthalimide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole; resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, or the like; catechol; hydroquinone; substituted hydroquinones such as 2-methyl hydroquinone, 2-ethyl hydroquinone, 2-propyl hydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, chlorohydroquinone, acetoxyhydroquinone, and nitrohydroquinone.

In particular embodiments, the Ar may be derived from bisphenol A and R may be a methyl group providing polyphosphonates, phosphonate copolymers, random and block co-oligo(phosphonate carbonate)s and co-oligo(phosphonate ester)s, and oligomeric phosphonates that may have structures such as, but not limited to, structures of Formulae III:

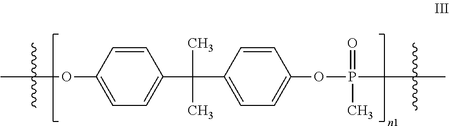

In some embodiments, a single aromatic diol may be used, and in other embodiments, various combinations of such aromatic diols may be incorporated into the polymer. The phosphorous content of phosphonate component may be controlled by the molecular weight (MW) of the aromatic diol used in the oligomeric phosphonates, polyphosphonates, or copolyphosphonates. A lower molecular weight aromatic diol may produce an oligomeric phosphonate, polyphosphonate, or copolyphosphonate with a higher phosphorus content. An aromatic diol, such as resorcinol, hydroquinone, or a combination thereof or similar low molecular weight aromatic diols may be used to make oligomeric phosphonates or polyphosphonates with high phosphorous content. The phosphorus content, expressed in terms of the weight percentage, of the phosphonate oligomers, phosphonates, or copolyphosphonates may be in the range from about 2 wt. % to about 18 wt. %, about 4 wt. % to about 16 wt. %, about 6 wt. % to about 14 wt. %, about 8 wt. % to about 12 wt. %, or a value between any of these ranges. In some embodiments, phosphonate oligomers, polyphosphonates, or copolyphosphonates prepared from bisphenol A or hydroquinone may have phosphorus contents of 10.5 wt. % and 18 wt. %, respectively.

Description Polyphosphonates

In certain embodiments, the phosphonate component may be a polyphosphonate containing long chains of the structural unit of Formula I. In some embodiments, the polyphosphonates may have a weight average molecular weight (Mw) of about 10,000 g/mole to about 100,000 g/mole as determined by GPC, and in other embodiments, the polyphosphonates may have an Mw of from about 12,000 to about 80,000 g/mole as determined by GPC. The number average molecular weight (Mn) in such embodiments may be from about 5,000 g/mole to about 50,000 g/mole, or from about 8,000 g/mole to about 15,000 g/mole, and in certain embodiments the Mn may be greater than about 9,000 g/mole. The molecular weight distribution (i.e., Mw/Mn) of such polyphosphonates may be from about 2 to about 10 in some embodiments and from about 2 to about 5 in other embodiments.

In certain embodiments, the phosphonate component may be a polyphosphonate containing branched structures of the structural unit of Formula I. In some cases, a branching agent (i.e. tri or tetrahydroxy aromatic compound) may be added or it may be generated in-situ via a reaction of bisphenol A and an appropriate catalyst. In some embodiments, the branched polyphosphonates may have a molecular weight distribution (i.e., Mw/Mn) of from about 2 to about 10 in some embodiments and from about 2.3 to about 3.2 in other embodiments.

Description Phosphonate Copolymers

In some embodiments, the phosphonate component may be copolymers containing carbonate linkages [i.e., copoly(phosphonate carbonate)] or ester linkages [i.e., copoly(phosphonate esters)].

For example, copoly(phosphonate carbonate)s may include repeating units derived from at least 20 mole percent high purity diaryl alkylphosphonate or optionally substituted diaryl alkylphosphonate, one or more diaryl carbonate, and one or more aromatic dihydroxy compounds, wherein the mole percent of the high purity diaryl alkylphosphonate is based on the total amount of transesterification components, i.e., total diaryl alkylphosphonate and total diaryl carbonate. As indicated by the term “random” the monomers of the copoly(phosphonate carbonate)s of various embodiments may be incorporated into polymer chain randomly. Therefore, the polymer chain may include alternating phosphonate and carbonate monomers linked by one or more aromatic dihydroxide and/or various segments in which several phosphonate or several carbonate monomers form phosphonate or carbonate segments. Additionally, the length of various phosphonate or carbonate segments may vary within individual copoly(phosphonate carbonate)s.

The phosphonate and carbonate content of the copoly(phosphonate carbonate)s may vary among embodiments, and embodiments are not limited by the phosphonate and/or carbonate content or range of phosphonate and/or carbonate content. For example, in some embodiments, the copoly(phosphonate carbonate)s may have a phosphorus content of from about 1% to about 20% by weight of the total copoly(phosphonate carbonate), and in other embodiments, the phosphorous content of the copoly(phosphonate carbonate)s of the invention may be from about 2% to about 10% by weight of the total polymer.

In other embodiments, the copoly(phosphonate carbonate)s or copoly(phosphonate ester)s, may have structures such as, but not limited to, those structures of Formulae IV and V, respectively:

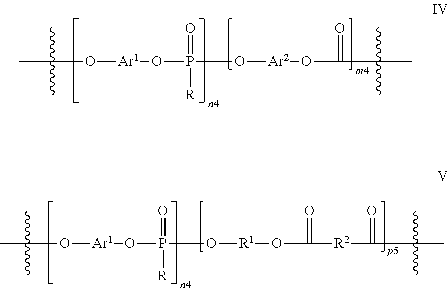

and combinations thereof, where Ar1 and Ar2 are each, independently, an aromatic group and —O—Ar1-O— and —O—Ar2-O— may be derived from a dihydroxy compound as described by structure (II).

R is a C1-20 alkyl, C2-20 alkene, C2-20 alkyne, C5-20 cycloalkyl, or C6-20 aryl. R1 may be a C1-20 alkylene or cycloalkylene, such as methylene, ethylene, propylene, butylene, pentylene, and the like, and in particular embodiments, R1 can be derived from aliphatic diols such as, but not limited to, 1,4-cyclohexyldimethanol, 1,4-butane diol, 1,3-propane diol, ethylene diol, ethylene glycol, and the like and combinations thereof. R2 is, independently, a C1-20 alkylene, C2-20 alkylenylene, C2-20 alkylynylene, C5-20 cycloalkylene, or C6-20 arylene, each Z1 is, independently, C1-20 alkylene, C2-20 alkylenylene, C2-20 alkylynylene, C5-20 cycloalkylene, or C6-20 arylene. In certain embodiments, R2 can be derived from adipic acid, dimethyl terephthalic acid, terephthalic acid, isophthalic acid, naphthalene dicarboxylic acid and the like or derivatives thereof or combinations thereof. In certain embodiments, R2 may be an aromatic group such as naphthalene, phenylene, biphenylene, propane-2,2-diyldibenzylene, and in some embodiments, R2 can be derived from, for example, dimethyl terephthalate, dimethyl isophthalate, dimethyl naphthalate, and the like and combinations thereof. Thus, R2 may be, for example, naphthalene, phenyl, both of which may be substituted at any position on the rings.

Such copoly(phosphonate carbonates) or copoly(phosphonate esters) may be block copoly(phosphonate carbonates) or copoly(phosphonate esters) in which each m, n, and p is greater than about 1, and the copolymers contain distinct repeating phosphonate and carbonate blocks or phosphonate and ester blocks. In other embodiments, the copoly(phosphonate carbonates) or copoly(phosphonate esters) can be random copolymers in which each m4, n4, and p5 are each, independently, an integer from 1 to about 200, 1 to about 100, 1 to about 75, 1 to about 50, 1 to about 20, 1 to about 10, or 1 to about 5, or any integer between these ranges.

In particular embodiments, the Ar1 and Ar2 may be derived from bisphenol A and R may be a methyl group providing random and block co(phosphonate carbonate)s and co(phosphonate ester)s that may have structures such as, but not limited to, structures of Formulae VI and VII:

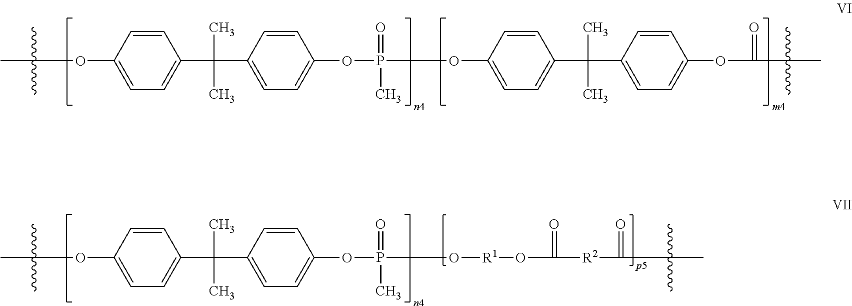

and combinations thereof, where each of m, n, p, and R1 and R2 are defined as described above.

The copoly(phosphonate carbonate)s of various embodiments exhibit both a high molecular weight and a narrow molecular weight distribution (i.e., low polydispersity). For example, in some embodiments, the copoly(phosphonate carbonate)s may have a weight average molecular weight (Mw) of about 10,000 g/mole to about 100,000 g/mole as determined by GPC, and in other embodiments, the copoly(phosphonate carbonate)s may have a Mw of from about 12,000 to about 80,000 g/mole as determined by GPC. The number average molecular weight (Mn) in such embodiments may be from about 5,000 g/mole to about 50,000 g/mole, or from about 8,000 g/mole to about 15,000 g/mole, and in certain embodiments the Mn may be greater than about 9,000 g/mole. The narrow molecular weight distribution (i.e., Mw/Mn) of such copoly(phosphonate carbonate)s may be from about 2 to about 7 in some embodiments and from about 2 to about 5 in other embodiments.

Additional Description Phosphonate Oligomers

In some embodiments, the molecular weight (weight average molecular weight as determined by gel permeation chromatography based on polystyrene calibration) range of the oligophosphonates, random or block co-oligo(phosphonate ester)s and co-oligo(phosphonate carbonate)s may be from about 500 g/mole to about 18,000 g/mole or any value within this range. In other embodiments, the molecular weight range may be from about 1,500 g/mole to about 15,000 g/mole, about 3,000 g/mole to about 10,000 g/mole, or any value within these ranges. In still other embodiments, the molecular weight range may be from about 700 g/mole to about 9,000 g/mole, about 1,000 g/mole to about 8,000 g/mole, about 3,000 g/mole to about 4,000 g/mole, or any value within these ranges.

The oligomeric phosphonates can have about 60% to about 100% of the total of oligomeric phosphonates have two or more reactive end-groups. In other embodiments, about 75% to about 99% of the total of oligomeric phosphonates have two or more reactive end-groups. In some embodiments, the reactive end-groups may be, for example, epoxy, vinyl, vinyl ester, isopropenyl, isocyanate, or combinations thereof, and in certain embodiments, about 80% to about 100% of the total oligomeric phosphonates may have two or more hydroxyl end groups. In various embodiments, the oligomeric phosphonates or portions thereof may include oligophosphonate, random co-oligo(phosphonate ester), block co-oligo(phosphonate ester), random co-oligo(phosphonate carbonate), block co-oligo(phosphonate carbonate), or combinations thereof. In some embodiments, the oligomeric phosphonates may include linear oligomeric phosphonates, branched oligomeric phosphonates, or a combination thereof, and in other embodiments, such oligomeric phosphonates may further include hyperbranched oligophosphonates.

The polymer compositions of various embodiments may further exhibit low dielectric constant (Dk) and low dielectric dissipation factor (Df). For example, in some embodiments, the compositions described above having a polyphenylene ether component, a phosphonate component and a crosslinking agent may exhibit a Dk of 3.6 and a Df of 0.005 at 10 gigahertz (GHz). In other embodiments, the compositions described above may exhibit a Dk of about 0.5 to about 4.0, about 1.0 to about 3.5, or about 1.5 to about 3.5 at 10 GHz or any individual value or range encompassed by these example ranges and a Df of about 0.0001 to about 0.01 or about 0.0005 to about 0.005 at 10 GHz or any individual value or range encompassed by these example ranges. In particular embodiments, the polymer compositions described above may have a combination of both low Dk and low Df as indicated by these example ranges, and in some embodiments, the polymer compositions may exhibit one of a low Dk or a low Df.

The compositions described above may include additional components such as additives, inorganic fillers such as silica or alumina trihydrate (ATH)

In such embodiments, the additives or fillers make up from about 1 wt. % to about 60 wt. %, of the total composition.

Polymer compositions described above including a polyphenylene ether resin and, a phosphonate component, crosslinking agent and optionally a second resin can be prepared by conventional means. For example, in some embodiments, the compositions may be prepared by dissolving in a solvent to dissolve the components, coating the glass fabric and then removing the solvent from the coated fabric (prepreg). In such embodiments, the reaction mixture may be stirred for sufficient time to allow the various components to dissolve completely. The step of removing the solvent from the prepreg can be carried out by any means. For example, in some embodiments, the step of removing the solvent can be carried out at room temperature or by gently heating the prepregs to allow the solvent to completely evaporate. In particular embodiments, the solvent can be removed at a temperature of about 50° C. to about 100° C.

In certain embodiments, the method may further include the step of curing the glass fabric after removing the solvent. The resin mixture can be coated onto glass fabric, several layers of which are layered together under a hot press make laminates. Curing can be carried out by conventional means such as, for example, putting the prepregs in an press and using a curing profile from room temperature about 22° C. to about 250° C. or about 22° C. to about 200° C. for about 40 minutes to about 240 minutes, about 40 minutes to about 200 minutes, or about 60 minutes to about 180 minutes or any individual time period or range encompassed by this time period.

The solvent of use to dissolve the reaction mixture may be any solvent known in the art including, for example, can include, but are not limited to, perfluorohexane, a,a,a-trifluorotoluene, pentane, hexane, cyclohexane, methylcyclohexane, decalin [c+t], dioxane, carbon tetrachloride, freon-11, benzene, toluene, triethyl amine, carbon disulfide, diisopropyl ether, diethyl ether (ether), t-butyl methyl ether (MTBE), chloroform, ethyl acetate, 1,2-dimethoxyethane (glyme), 2-methoxyethyl ether (diglyme), tetrahydrofuran (THF), methylene chloride, pyridine (Py), methyl ethyl ketone (MEK), methyl n-amyl ketone (MAK), methyl n-propyl ketone (MPK), acetone, hexamethylphosphoramide, N-methylpyrrolidinone, nitromethane, dimethylformamide, acetonitrile, sulfolane, dimethyl sulfoxide, propylene carbonate, and the like. In certain embodiments, the solvent may be methyl ethyl ketone (MEK) or acetone. The amount of solvent included in the mixtures of various embodiments may be from about 25 wt. % to about 75 wt. % of the total composition, and in certain embodiments, the solvent may be about 30 wt. % to about 50 wt. % of the total composition or any concentration or range encompassed by these example ranges.

In certain embodiments, the reaction mixture may further include a catalyst, such as a Lewis base or a Lewis acid. Lewis bases useful in embodiments include, for example, imidazole, boron trifluoride amine complex, ethyltriphenyl phosphonium chloride, 2-methylimidazole (2MI), 2-phenyl-1H-imidazole (2PZ), 2-ethyl-4-methylimidazole (2E4MI), triphenylphosphine (TPP), and/or 4-dimethylaminopyridine (DMAP). Lewis acids useful in embodiments include metal salt compounds, such as a manganese, iron, cobalt, nickel, copper, or zinc metal salts, for example, zinc caprylate or cobalt caprylate. The amount of the catalyst may be any amount that is effective for use as a catalyst and can, generally, be from about 0.01 wt. % to about 20 wt. % based on the weight of the total composition. In some embodiments, the amount of catalyst may be, about 0.1 wt. % to about 15 wt. %, about 0.5 wt. % to about 10 wt. %, about 1.0 wt. % to about 5 wt. %, or any range or individual concentration encompassed by these example ranges.

The polymer compositions of various embodiments can be used in any application in which a flame retardant polymer is useful. For example, in some embodiments, the polymer compositions of the invention may be used as coatings on plastics, metals, glass, carbon, ceramic, or wood products which can be in a variety of forms, for example as a fiber, woven mat, nonwoven mat, cloth, broadgood, fabric, molding, laminate, foam, extruded shape or the like, and in other embodiments, the polymer compositions of the invention can be used in adhesives or to fabricate sheets, multilayer sheets, free-standing films, multi-layer films, fibers, foams, molded articles, and fiber reinforced composites.

In particular embodiments, the compositions of the invention may be used in copper clad laminates (CCL). Such laminates may be used to fabricate components such as flexible or rigid laminated circuit boards that can be incorporated into articles of manufacture such as electronic goods such as, for example, televisions, computers, laptop computers, tablet computers, printers, cell phones, video games, DVD players, stereos and other consumer electronics that must meet UL or other standardized fire resistance standards and environmental standards.

### EXAMPLES

Materials
[A] Nofia phosphonate oligomer OL3001 and HM5000, FRX Polymers Inc.
[B] Noryl SA90 (hydroxyl endgroups) and SA9000 (vinyl endgroups) polyphenylene oxide (PPO) oligomers, SABIC.
[C] Epoxy Resin 1: BisA novolac epoxy resin 157S70, Mitsubishi Chemical Corporation
[D] Epoxy Resin 2: Biphenyl epoxy NC-3000-H, Nippon Kayaku
[E] Epoxy Resin 3: Epon 154, Hexion Inc.
[F] Catalyst 1: 2-ethyl-4-methyl-imidazole (2E4MI), Alfa Aesar
[G] Catalyst 2: 1,8-diaza-bicyclo[5.4.0]undec-7-ene (DBU), Alfa Aesar
[H] Catalyst 3: dicumyl peroxide (DCP), Aldrich Chemical
[I] Catalyst 4: 4-(dimethyl amino) pyridine (DMAP), Alfa Aesar
[J] Triallyl isocyanurate (TAIC), Aldrich Chemical
[H] Triglycidyi isocyanurate, Araidite PT810 (TGIC), Huntsman
[K] Glycidyl methacrylate (GMA), Aldrich

### Analytical Methods

Glass transition temperatures were measured by Differential Scanning calorimetry (DSC) using the TA Instruments Q2000 model and Dynamic Mechanical Analysis (DMA) using the Discovery Hybrid Rheometer (DHR1). For both measurements, a ramp rate of 10° C./min was used. Permittivity and Loss tangent (Dk/Df) of the laminate samples were measured at 1GHz per the IPC-TM-650 Method 2.5.5.9 Permittivity and Loss Tangent, Parallel Plate method.

### Flame Retardancy Testing

A UL 94 vertical burn chamber was used for screening of the test samples. The bars were suspended along the vertical axis and a ¾ inch flame applied to the sample for 10 seconds. After the sample extinguishes, the flame is re-applied to the sample for another 10 seconds. The time to self-extinguish after the first (t₁) and second (t₂) flame exposure was recorded. For V0 rating, the maximum burning time after removal of the ignition flame (tmax) should not exceed 10 seconds and the total burning time (t1+t2) for five tested specimens should not exceed 50 seconds. No rating (NR) indicates one or more of the samples burned for longer than 30 seconds.

### Sample Preparation

Formulations containing various epoxy resins, phosphonate oligomer, Noryl PPO and catalyst were prepared by dissolving in MEK at 60 wt % solids.

### Laminate Preparation

Prepregs were prepared using 7628 glass fabric or 2116 glass fabric. Fabric pieces (5×5 inches) were coated with the resin formulations and dried overnight in air. The prepregs were stacked in 4 or 5 layers and laminated (without copper) in a press, with a final cure temperature of 200° C. for 90 minutes.

### Examples 1-4

Formulations containing a range of loadings of the phosphonate oligomer Nofia OL3001 and the PPO oligomer SA90 are shown in Examples 1-4 summarized in Table 1. Laminates were made from 4 prepreg layers of 7628 glass. Comparative examples 1-4 show formulations and laminates prepared containing epoxy resins 1-3 and only Nofia OL3001. The results show higher Tg's were obtained when SA90 was added at 5.6 wt % and/or 20 wt % for epoxy resins 1 and 2, but similar Tg's for epoxy 3 with 20 wt % SA90 (example 5 and comp example 4). In addition, with the addition of SA90, the loading levels of Nofia OL3001 could be reduced and still meet the V0 requirements.

TABLE 1

| | | | | | | Comp | Comp | Comp | Comp |
|---|---|---|---|---|---|---|---|---|---|
| Example | 1 | 2 | 3 | 4 | 5 | Ex 1 | Ex 2 | Ex 3 | Ex 4 |
| Epoxy 1 | 48.95 | 0 | 0 | 0 | 0 | 59.95 | 0 | 0 | 0 |
| Epoxy 2 | 0 | 64.0 | 63.8 | 54.4 | 0 | 0 | 66.7 | 66.6 | 0 |
| Epoxy 3 | 0 | 0 | 0 | 0 | 47.6 | 0 | 0 | 0 | 56.6 |
| OL3001 | 30 | 30 | 30 | 25 | 32 | 40 | 33 | 33 | 43 |
| SA90 | 21 | 5.6 | 5.6 | 20 | 20 | 0 | 0 | 0 | 0 |
| 2E4MI | 0.05 | 0 | 0 | 0 | 0 | 0.05 | 0.3 | 0 | 0 |
| DBU | 0 | 0.4 | 0.6 | 0.6 | 0.4 | 0 | 0 | 0.4 | 0.4 |
| Thickness (mm) | 0.54 | 0.55 | 0.57 | 0.65 | 0.58 | 0.63 | 0.59 | 0.53 | 0.64 |
| Tg (°C., DSC) | 175 | 153 | 167 | 168 | 161 | 164 | 143 | 135 | 160 |
| UL94 | V0 | V0 | V0 | V0 | V0 | V0 | V0 | V0 | V0 |

Table 2 shows the comparison of the epoxy resin 2 with and without the PPO product SA9000. Example 6 shows the combination of SA9000 and Nofia HM5000 can be co-reacted with TAIC and epoxy resin 2 respectively. The TAIC has vinyl functionality used to crosslink with the vinyl end groups of the SA9000, and the phosphonate groups of the Nofia OL3001 react with the epoxy groups during the lamination process forming a crosslinked structure. The laminate in example 6 had a single Tg measured at 206° C., while the comparative example 5 of the laminate without SA9000 had lower Tg of 185° C. The epoxy-PPO sample also had a lower Dk of 3.9 and lower Df of 0.005 at 1 GHz vs Dk 4.4 and Df 0.008 values at 1 GHz of the pure epoxy sample.

TABLE 2

Example

| | | Comp |
|---|---|---|
| | 6 | Ex 5 |
| SA9000 | 40 | 0 |
| Nofia OL3001 | — | 33 |
| Nofia HM5000 | 13 | 0 |
| Epoxy 2 | 27 | 67 |
| TAIC | 20 | 0 |
| DCP | 0.8 | |
| DMAP | 0.15 | 0.15 |
| Thickness (mm) | 0.61 | 0.42 |
| Tg (° C., DMA) | 206 | 185 |
| Dk @ 1 GHz | 3.9 | 4.4 |
| Df @ 1 GHz | 0.005 | 0.008 |

Table 3 shows examples using TAIC and 2 other crosslinking agents. Formulations in example 7 and 8 contain triglycidyl isocyanurate (TGIC), while example 9 was prepared using glycidyl methacrylate (GMA). These crosslinking agents contains both vinyl and epoxy functionality and were selected to ensure reaction with both the SA9000 and Noryl OL3001 during lamination. Comparative example 6 contains only the TAIC crosslinking agent. The laminate data indicate higher crosslink density when the additional crosslinking agent is used, indicated by higher Tg's >220° C. In all cases when both the phosphonate and polyphenylene ether resins are combined, the Df at 1 GHz is equal or lower than 0.005

TABLE 3

Example

| | | | | Comp |
|---|---|---|---|---|
| | 7 | 8 | 9 | Ex 6 |
| SA9000 | 45 | 55 | 45 | 53 |
| Nofia HM5000 | 17 | 11 | 16 | 19 |
| TAIC | 24 | 24 | 22 | 27 |
| TGIC | 13 | 9 | 0 | 0 |
| GMA | 0 | 0 | 16 | 0 |
| DCP | 0.8 | 0.8 | 0.8 | 0.8 |
| DMAP | 0.15 | 0.15 | 0.15 | 0 |
| Thickness (mm) | 0.68 | 0.67 | 0.59 | 0.72 |
| Tg (° C., DMA) | 221 | 223 | 221 | 215 |
| Dk @ 1 GHz | 4.0 | 4.0 | — | 3.6 |
| Df @ 1 GHz | 0.005 | 0.005 | — | 0.003 |

1. A curable composition comprising
phosphonate oligomer, polymer or copolymer;
a polyphenylene ether resin; and
a crosslinking compound.

2. The composition of claim 1 where the crosslinking compound comprises vinyl functionality, epoxy functionality, or both vinyl and epoxy functionality, or both vinyl and hydroxy functionality.

3. The composition of claim 2 where the crosslinking compound comprises of triallyl isocyanurate, triglycidyl isocyanurate, glycidyl methacrylate, 4-(glycidyloxy)-styrene, vinyl benzyl alcohol, 2-(4-ethenylphenoxymethyl)oxirane, vinyl terminated phosphonate oligomer

4. The composition of claim 1 where the phosphonate copolymer contains phosphonate groups and carbonate groups or ester groups

5. The composition of claim 1 comprising 30 wt % or less phosphonate component and wherein the composition meets V0 at 0.65 mm or less.

6. The composition of claim 1 comprising 30 wt % or less phosphonate component and wherein the composition has a Df at 1 GHz<0.007.

7. The composition of claim 1 having a Tg of at least 200° C. when measured with DMA.

8. A curable composition comprising
phosphonate oligomer, polymer or copolymer;
a polyphenylene ether resin;
one or more co-resin; and
a crosslinking compound.

9. The composition of claim 8 where the co-resin is an epoxy resin, a cyanate ester, or benzoxazine resin

10. The composition of claim 9 comprising 30 wt % or less phosphonate component and wherein the composition meets V0 at 0.65 mm or less.

11. The composition of claim 9 comprising 30 wt % or less phosphonate component and wherein the composition has a Df at 1 GHz<0.007.

12. The composition of claim 9 having a Tg of at least 200° C.

13. A prepreg formulation comprising:
a thermosetting resin formulation comprising:
a phosphonate oligomer, polymer or copolymer;
a polyphenylene ether resin; and
a crosslinking compound,
wherein the thermosetting resin formulation is impregnated onto a reinforcing material.

14. A laminate comprising:
a prepreg comprising:
a thermosetting resin formulation comprising:
a phosphonate oligomer, polymer or copolymer;
a polyphenylene ether resin; and
a crosslinking compound,
wherein the thermosetting resin formulation is impregnated onto a reinforcing material.
